(19) United States
(12) Patent Application Publication
(10) Pub. No.: US 2014/0073278 A1
(43) Pub. Date: Mar. 13, 2014

(54) RSSI estimation based on VGA control and threshold detection

(71) Applicants: Yiping Fan, Hsinchu City (TW); Chun-Yuan Lin, Pingtung County (TW); Li-Feng Chen, New Taipei City (TW); Sheng-Chia Huang, Hsinchu City (TW)

(72) Inventors: Yiping Fan, Hsinchu City (TW); Chun-Yuan Lin, Pingtung County (TW); Li-Feng Chen, New Taipei City (TW); Sheng-Chia Huang, Hsinchu City (TW)

(73) Assignee: UNIBAND ELECTRONIC CORP., Hsin-Chu (TW)

(21) Appl. No.: 13/607,822

(22) Filed: Sep. 10, 2012

(51) Int. Cl. H03G 3/20

(52) U.S. Cl. 455/253.2

(57) ABSTRACT

A circuit for RSSI estimation includes a cascaded chain of variable gain amplifier stages, a threshold detector configured to output an indication signal according to a comparison of output of the cascaded chain of variable gain amplifier stages with a predetermined threshold, and an automatic gain controller configured to adjust gain of at least one variable gain amplifier of the cascaded chain of variable gain amplifier stages according to the indication signal. Each stage may include a switch module configured to electrically connect or disconnect an input of the variable gain amplifier of the at least one variable gain amplifier stage to/from an output of a previous variable gain amplifier stage according to a switch control signal.

### BACKGROUND OF THE INVENTION

1. Field of the Invention

This application relates to adjusting signal amplification, and more particularly to RSSI estimation.

2. Description of the Prior Art

Received signal strength indication (RSSI), is used very often to access whether a radio frequency (RF) channel is clear or how strong the RF signal or interference is. In conventional RSSI detection or estimation, a section of serially linked limiting amplifiers and rectifiers are used to generate an analog signal, which is typically sampled by an analog to digital converter (ADC).

Please refer to FIG. 1 which illustrates a conventional RSSI estimation system 100. The received signal is generally outputted from a channel filter 135 into a plurality of serially linked limiting amplifiers (LA) 110 of the RSSI estimator 110. The signal between each of the limiting amplifiers 115 is rectified by a full wave rectifier (FWR) 120 and the rectified signal is output to an analog-to-digital (ADC) unit 125 as shown.

Use of these components not only occupies a significant portion of an analog circuit in an RF receiver, but also requires a large amount of current.

### SUMMARY OF THE INVENTION

A circuit for RSSI estimation is proposed. The circuit may include a cascaded chain of variable gain amplifier stages, a threshold detector configured to output a indication signal according to a comparison of output of the cascaded chain of variable gain amplifier stages with a predetermined threshold, and an automatic gain controller configured to adjust gain of at least one variable gain amplifier of the cascaded chain of variable gain amplifier stages according to the indication signal. Each stage may include a variable gain amplifier, a switch module, and a high pass filter. The switch module may be configured to electrically connect or disconnect an input of the variable gain amplifier of the at least one variable gain amplifier stage to/from an output of a previous variable gain amplifier stage according to a switch control signal.

A method for RSSI estimation is further disclosed. The method includes amplifying a received input signal using a cascaded chain of variable gain amplifier stages, comparing output of the cascaded chain of variable gain amplifier stages with a predetermined threshold and outputting results of the comparison as a indication signal, and adjusting gain of at least one variable gain amplifier of the cascaded chain of variable gain amplifier stages according to the indication signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a traditional RSSI approach.

FIG. 2 is a block diagram of an RSSI approach according to an embodiment of the invention.

FIG. 3 illustrates an example of DC offset induced detection error.

FIG. 4 illustrates an example of DC removal behavior.

FIG. 5 is a more detailed block diagram of an RSSI approach according to an embodiment of the invention.

FIG. 6 illustrates a binary decision tree according to an embodiment of the invention.

### DETAILED DESCRIPTION

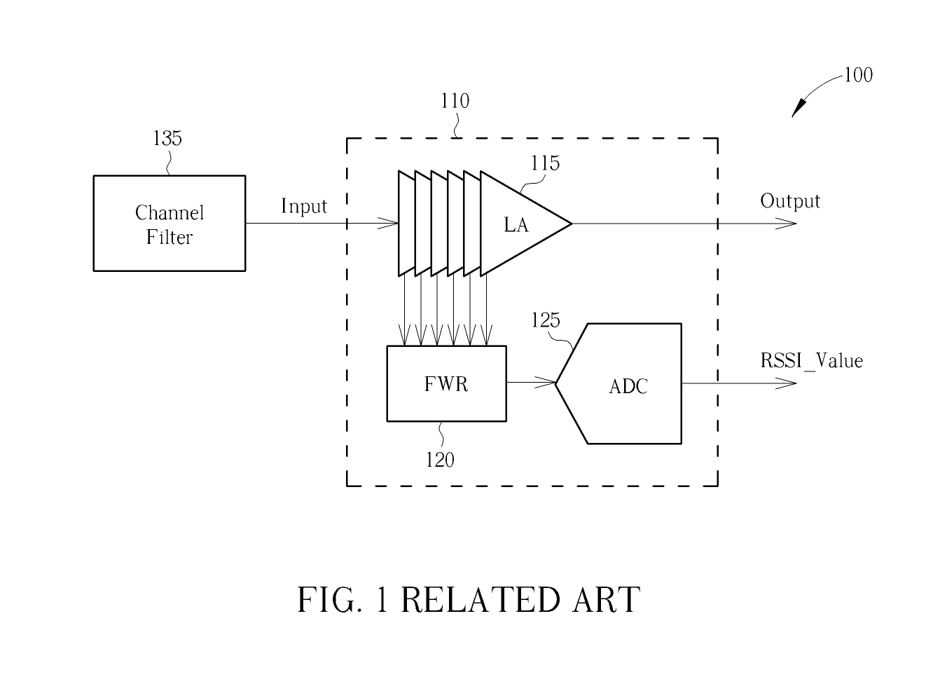

In the prior art, RSSI is typically detected with the method shown in FIG. 1 and it may be used to control the gain. In contrast, the present invention discloses a novel, reversed thinking approach. The basic idea allowing this new approach to work is that with a constant level at the receiver output, the receiver's gain is inversely proportional to the signal level presented at the receiver's input. This means, by compensating with some constant offset, one can use a variable gain amplifier's (VGA) gain to estimate the RSSI.

The question is how to control the VGA gain? For the most efficient implementation, a digitally controlled VGA is used as an example; however the concept can be extended into an analog controlled VGA without departing from the scope of the invention. The step size of the digitally controlled VGA determines the resolution and error of the RSSI detection.

Initially, the VGA is set at the highest gain or a relative high gain so that the desired RF signal will trigger a threshold detector, which compares the received signal to a predetermined constant threshold. This initial gain is set so that the decodable RF signal will trigger the threshold detector but minimize the chance of false triggers due to thermal or circuit noise effects.

When the threshold detector output, which is a digital signal, is sampled by the state machine, the state machine determines if the triggering is caused by signal or noise with multiple samples. If the state machine determines the triggering is due to RF signal or interference, it adjusts the VGA gain in such a way that the final gain and the gain adjustment most nearly preceding the final gain will make the polarity of the threshold detector's output alternate except at the lowest gain.

After the gain adjustment procedure is finish and the final gain value is close to an expected gain which is needed for the receiving signal, an automatic gain controller (AGC) will transfer the gain value information into an RSSI value, then output to other outside application blocks.

In the proposed approach, a digitally controlled variable gain amplifier (VGA), a threshold detector, and an automatic gain controller (AGC) having a state machine which controls VGA gain are utilized so that the received signal at the threshold detector is around the required level. Meanwhile, a gain value to RSSI transformation scheme transfers the final gain value into RSSI value.

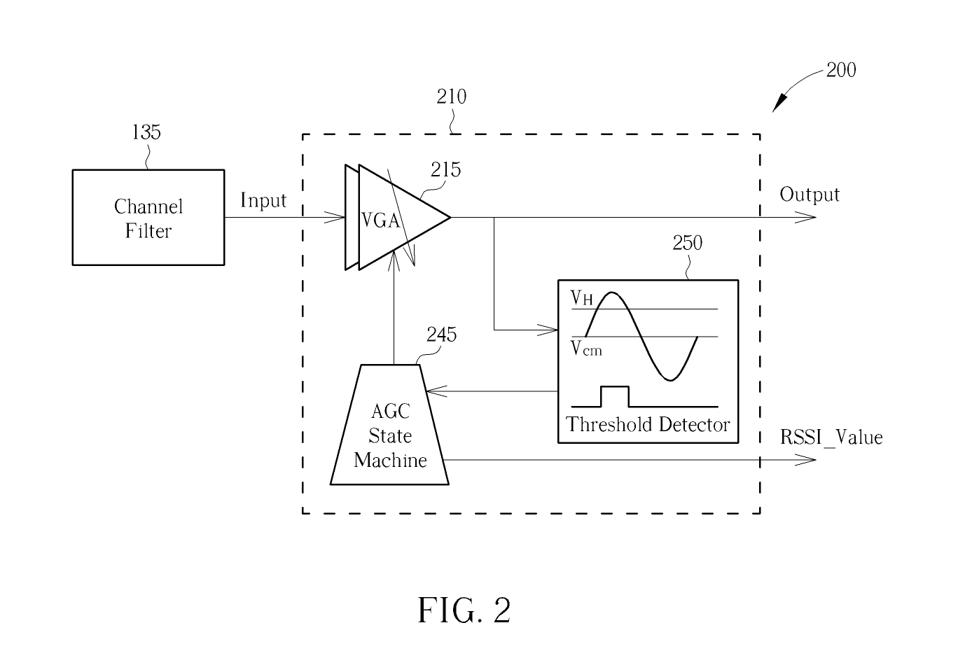

Please refer to FIG. 2 which is a block diagram of a proposed RSSI estimation system 200. In this embodiment, the RSSI estimator 210 comprises a plurality of serially linked variable gain amplifiers 215 receiving the received signal from the channel filter 135 and outputting to a threshold detector 250 as well as to other signal process units (not shown). The threshold detector 250 determines whether the output of VGA 215 exceeds a predefined threshold and sends an indication signal to the automatic gain control state machine 245. The gain of the VGA 215 is adjusted by the automatic gain control state machine 245 according to the indication signal received from the threshold detector 250.

During the VGA gain adjustment, many practical factors need to be considered, such as direct current (DC) and alternating current (AC) voltage signal settling of the VGA, or DC removal time. The goal is to make sure that the signal presented at the threshold detector is not distorted by the gain adjustment itself. There are many ways to search for the required gain, but once the final gain is reached, the state machine can indicate to the receiver that the RSSI is ready.

To minimize wrong triggering or lack of triggering due to noise, certain fault tolerance mechanisms can be built into the gain search algorithm. This new RSSI detection particularly fits well with a modulation having a constant envelope, such as frequency or phase modulation and its variants but is not limited to such.

In this new approach, a multi-stage VGA can be controlled by a digital AGC. Between each stage of the VGA, at least one high pass filter may be inserted to couple the AC signal to the next VGA stage. The output signal of final VGA stage high pass filter may be compared with a predetermined threshold voltage level, so that the gain of the VGA stage can be adjusted according to whether the current state is overflow or insufficient. This concept can be extended to a smarter searching algorithm base on the period of detected signal without departing from the scope of the invention. Finally, the state machine selects a gain to make amplitude of the signal around the predetermined level.

A state machine could provide a corresponding RSSI value according to selected gain. However, there are several challenges to this method.

First, since the output voltage of the VGA stages is compared with a DC voltage, the output common mode voltages (Vcm) under different conditions should be identical. The detection result would not be reliable if the compared sources vary due to environmental or manufacturing conditions or even be unknown. Therefore, it is necessary to provide a predictable or constant reference voltage to distinct the signal level.

Furthermore, an amount of instantaneous residual charge after gain adjustment leads to the DC level of VGA stage shifting which is undesirable. Additionally, the DC shift is a time varying value related to the voltage level before gain adjustment, so it is hard to predict or compensate.

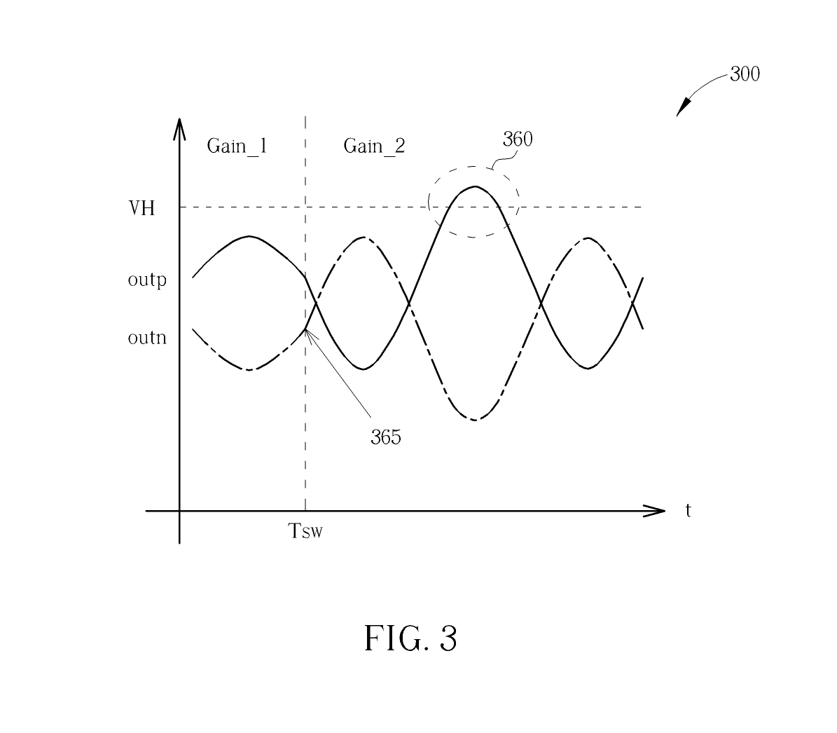

FIG. 3 shows an example 300 of how the DC shifting affects the detection results, with signal voltage indicated by the vertical axis and time t indicated by the horizontal axis. Assume the gain was changed from Gain_{—}1 to Gain_{—}2 at time Tsw 365, a time varying DC offset would be added into the positive outp and negative outn terminal with opposite polarity. As a result, one terminal of the signal would be higher than its real value, and it might be high enough to exceed the predefined threshold V_{H} as identified by the dotted circle 360, wrongly triggering the threshold detector. The multistage structure of the VGA would make this phenomenon very complex, therefore, the output is unidentified.

From the example of FIG. 3, a detection error can be evident as caused by gain adjustment, so that it would increase the difficulty of digital signal processing. To solve this problem, a DC removal mechanism is preferably used. The concept of this mechanism is to remove the DC shift value with each cycle of gain adjustment.

For this purpose, a switch module may be placed right before the VGA of each VGA stage. The switch modules separate the operation of the VGA stages into two modes, an amplifying mode and a DC removal mode. In the amplifying mode, the entire chain of VGA stages can amplify the input signal. Once the gain needs to be changed, the switch modules cause the chain of VGAs to enter DC removal mode. In this case, each VGA stage is isolated, the AC signal is blocked, and the residual charge can discharge quickly to reset the DC level of each VGA stage. Through the controlling of the state machine, these two modes can be alternately activated to search for the correct gain and provide a corresponding RSSI value after a few detection cycles.

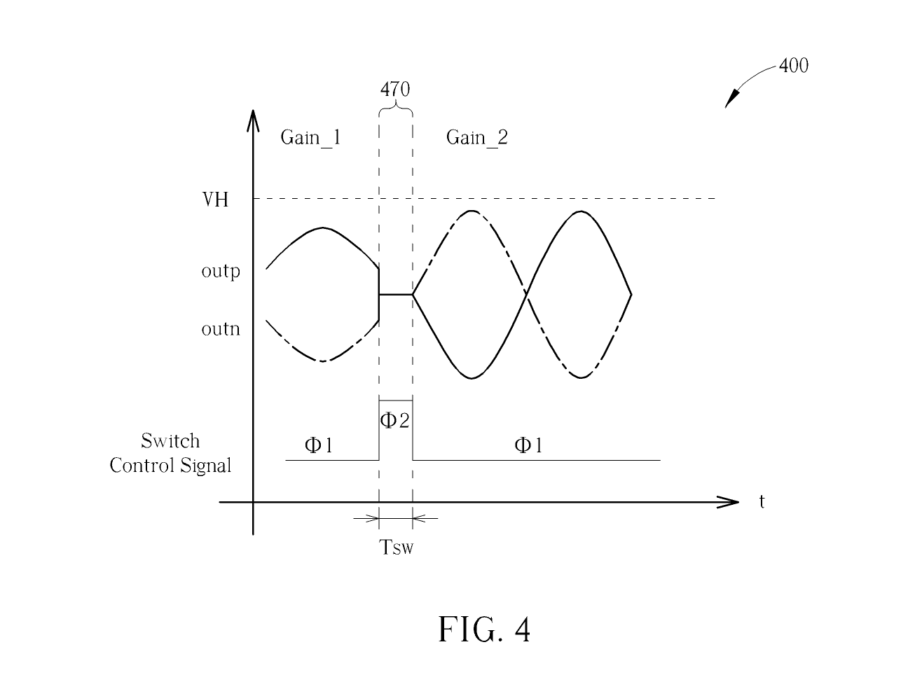

Please refer to FIG. 4 which shows the effect 400 of the proposed DC offset removal as the gain is again changed from Gain_{—}1 to Gain_{—}2. In FIG. 4, again the signal voltage is indicated by the vertical axis and time t indicated by the horizontal axis, VH indicates the predetermined voltage level, and outp and outn are respectively the outputs of the positive and negative terminals of the chain of VGA stages. The switch control signal marked as Φ1 indicate that the chain of VGAs is in the amplifying mode. Once VGA gain needs to be changed, the switch modules are controlled as indicated by Φ2 so that the chain of VGAs is in the DC removal mode during a DC removal period 470. The switch control signals Φ1 and Φ2 may be separate signals or may be different states of a single binary signal according to design considerations.

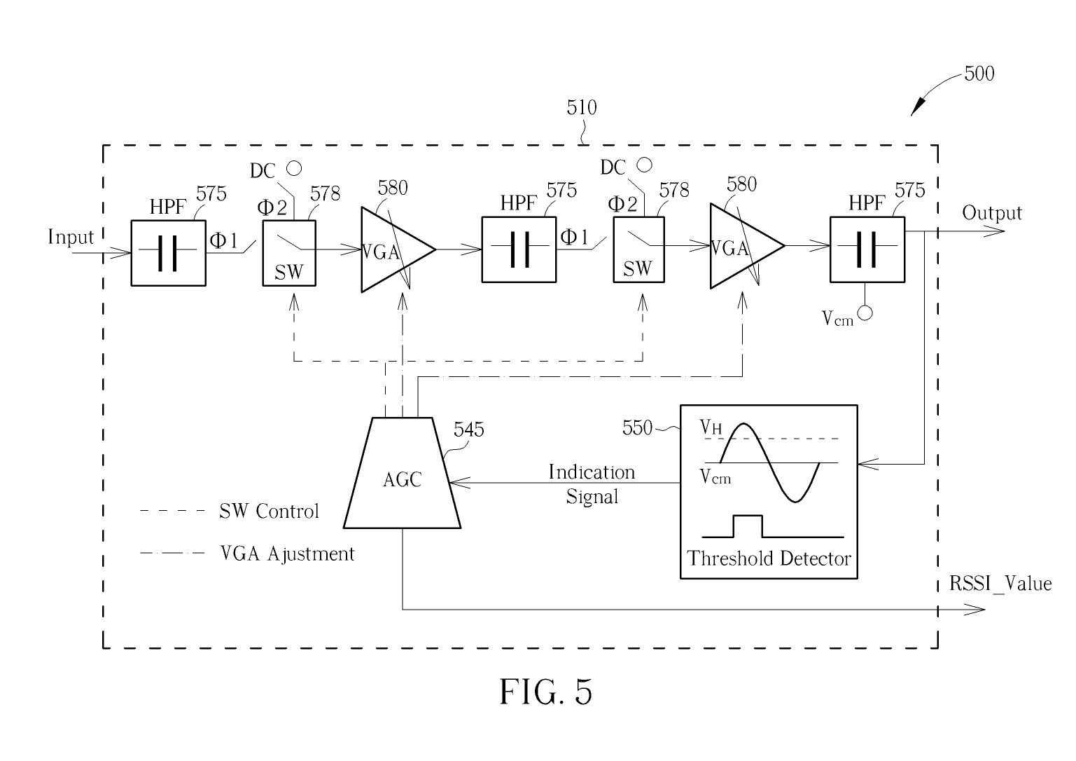

Please refer now to FIG. 5 that shows a more detailed block diagram 500 of an RSSI estimator 510 that includes the above DC offset removal method. In this embodiment, the RSSI estimator 510 comprises a cascaded chain of VGA 580 stages. Each stage of the chain of VGA 580 stages includes a VGA 580 coupled between a switch module 578 and a high pass filter 575 such that the input signals pass sequentially through a switch module 578 to a VGA 580 and on to the corresponding high pass filter 575. The recited serial coupling order of the switch module 578, the VGA 580, and the high pass filter 575 is preferred but may be different in other embodiments.

A threshold detector 550 may receive the output signal from the chain of VGA 580 stages and determine whether the signal exceeds a predefined threshold to generate an indication signal which is sent to an AGC 545. The state machine in the AGC 545 adjusts the gain of the chain of VGA 580 stages according to the indication signal generated by the threshold detector 550. Each stage of the chain of VGA 580 stages may be individually adjusted in some embodiments although any adjustment of at least one stage of the chain of VGA 580 stages according to results of the threshold detector 550 falls within the scope of the invention.

When the AGC 545 receives the indication signal from threshold detector 550 and indicates that adjustment of the chain of VGA 580 stages is needed, it sends a control signal to switch module 578 to activate amplifying mode and DC removal mode alternately for gain searching. Eventually, the AGC 545 will output a corresponding RSSI value according to the selected gain. The conversion equation from VGA gain to RSSI value can be formulated as

$$RSSI\_value = C - ( \frac{{2}^{N} - K}{{Gain}_{max}} \times {Gain}_{sel} ) . \qquad Equation ( 1 )$$

In equation (1), N is the preferred bit number of RSSI value, K is a design parameter to determine the output range, C is a constant to determine the maximum output value, and the Gain max and Gain sel are the maximum gain of VGA 580 and the final selected gain by AGC 545 respectively. Different formula may be utilized for mapping of VGA gain and RSSI value without departing from the scope of the invention.

Several gain searching methods may be used, such as inter alia, linear, step-wise, and brute force methods without departing from the scope of the invention. However to reduce whole task latency, a binary-decision approach to search for the exact gain value is preferred. In the disclosed cascaded VGA stage architecture, a maximum gain value may, for example, be assigned to be 48 dB (decibels), the minimum gain value is 0 dB and the step resolution of proposed gain control may be 3 dB. The binary-decision approach can be formulated as

$${Gain}_{init} = 48 bB , \\ {Gain}_{next} = 24 dB \\ While detect \neq 1 … v {\vert}_{v peak counting threshold} \\ \{ \frac{{{Gain}_{n + 1} = {Gain}_{n} + {( - 1 )}^{k} * {Gain}_{next} \vert}_{\begin{matrix}\underline{k = 0 if detect = 0} \\ k = 1 if detect > v\end{matrix}}}{{Gain}_{next} = {Gain}_{next} / 2 {\vert}_{{Gain}_{next} = 3 if {Gain}_{next} = 3 / 0}} \qquad Equation ( 2 )$$

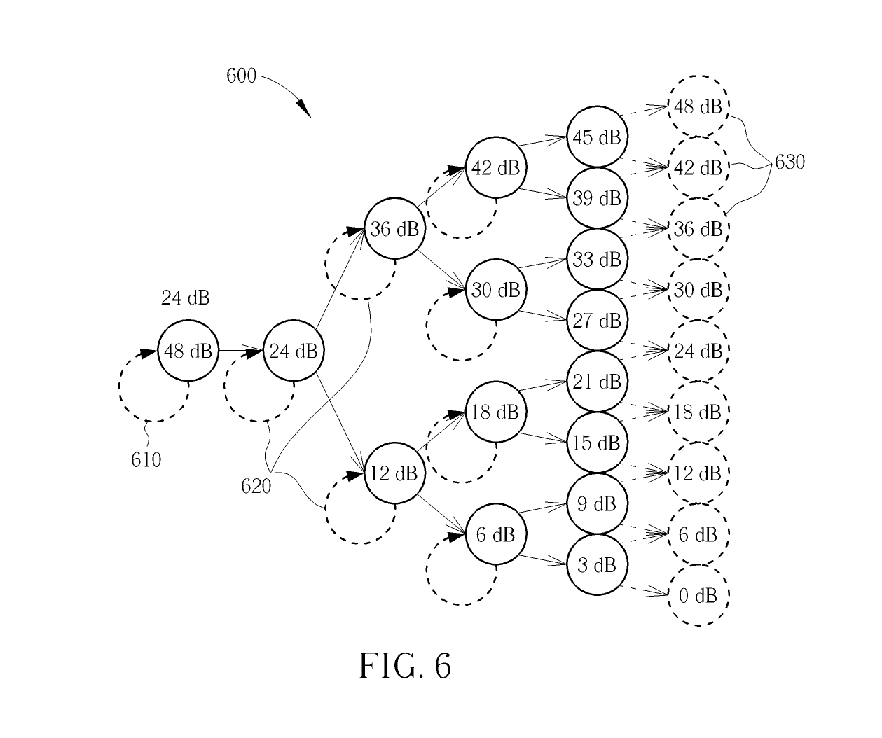

and the decision tree is shown in FIG. 6. In equation (2), the Gainₙₑₓₜ is a shifting half factor value for each peak detection iteration. In this equation, the repeat iteration number is log₂ (Gainₙₑₓₜ/3)=4, and the decision circles are shown in FIG. 6. The possible values in this example are 3, 6, 9 . . . 48 dB (decibels).

Due to an original binary decision algorithm being the ideal case and not flexible for real conditions, this method may be extended with four features: 1) waiting for incoming signal, 2) recheck & lock, 3) extending gain search, 4) time-out self-reset. These four features can enhance the proposed method for the real conditions.

### 1) Waiting for Incoming Signal

When the circuit powers on and there is not any signal received at the chain of VGA 580 stages, the threshold detector 550 will not output a result. Thus there is no peak detection information passing to the AGC 545. Suppose the state machine of the AGC 545 is running in this situation, the calculated value is holding at 48 dB, but the predefine iteration number (up to 4 in this example) was counted. Therefore a “turn-on and wait” mechanism that holds the initial gain value until the threshold detector 550 starts to output the indication signal as a pulse may be used. This mechanism can avoid unnecessary state machine transitions and keeps the controlled gain value at 48 dB until the threshold detector 550 outputs a result. This feature is represented as the leftmost dashed-line circular arrow 610 in FIG. 6.

### 2) Recheck & Lock

When the AGC 545 determines the best gain code for the chain of VGA 580 stages, the threshold detector 550 returns a predictable width pulse. Based on this pulse, the AGC 545 may generate the same control code for the chain of VGA 580 stages as a previous code. This flow will spend one extra calculation iteration, and the Gainₙₑₓₜ may be shifted to a wrong value. So a counter for counting same period pulses may be used. If the same period pulse is counted two times, it can be assumed that the gain value is stable, then the VGA control code is locked, and the decision tree may be abandoned for this gain estimation. This feature is shown in FIG. 6 as the dashed-lines circular arrows 620. Other unlabeled dashed-line circular arrows 620 are also shown at 6 dB, 18 dB, 30 dB, and 42 dB.

### 3) Extending Gain Search

Due to there not only being an expected signal but also non-ideal noise received at VGA input, the threshold detector may output variant width pulse. If the variant width pulse produces a wrong binary decision path, the difference between an exact gain result and calculated gain result is 6 dB in this example. To reduce the difference, the binary decision tree can be extended an additional iteration which compensates ±3 dB if needed. After this compensating operation, the proposed design will reduce the difference from 6 dB to 3 dB. This extending operation is shown as dashed-line circular arrows 630 at the rightmost portion of FIG. 6.

### 4) Time-Out Self-Reset

In multiple node access, packet-based application, the received signal may not always be sent from the same transmitter, so the received signal power may not always be the same. Besides, in packet-based transmission, the signal period is determinable. So the proposed RSSI estimator has to fine-tune itself for each transmission automatically. Therefore, a configurable counter is proposed that can cover all possible transmission latency. When the counter times out, the binary decision state machine of the AGC 545 can be reset automatically and the process of RSSI gain estimating is repeated. This operation can avoid a missed reset signal which should come from higher level control blocks.

Besides a single level threshold detector 545, a multi-level threshold detector can be used for a faster and more accurate gain adjustment. A tunable threshold for received signal level comparison can be applied to determine the desired power level to trigger the AGC. Some embodiments utilize V_{H} and the threshold detector 545 for this purpose.

Although the above disclosure recites examples used for RSSI estimation, it should be readily apparent to one skilled in the art that use of the RSSI estimator 510 of FIG. 5 can be extended beyond RSSI estimation and applied anywhere that a need to adjust gain value of a signal exists. Thus the scope of the invention is intended to include these applications.

Those skilled in the art will readily observe that numerous modifications and alterations of the device and method may be made while retaining the teachings of the invention. Accordingly, the above disclosure should be construed as limited only by the metes and bounds of the appended claims.

1: A circuit for RSSI estimation, the circuit comprising:
a cascaded chain of variable gain amplifier stages, each stage comprising a variable gain amplifier;
a threshold detector configured to output an indication signal according to a comparison of output of the cascaded chain of variable gain amplifier stages with a predetermined threshold; and
an automatic gain controller configured to adjust gain of at least one variable gain amplifier of the cascaded chain of variable gain amplifier stages according to the indication signal.

2: The circuit of claim 1 wherein the at least one variable gain amplifier stage further comprises a switch module configured to electrically connect or disconnect an input of the variable gain amplifier of the at least one variable gain amplifier stage to/from an output of a previous variable gain amplifier stage according to a switch control signal.

3: The circuit of claim 2 wherein when the switch module electrically disconnects the input of the variable gain amplifier of the at least one variable gain amplifier stage from the output of a previous variable gain amplifier stage according to the switch control signal, the switch module is further configured to electrically connect the input of the variable gain amplifier of the at least one variable gain amplifier stage to a predetermined DC voltage level.

4: The circuit of claim 3 wherein the at least one variable gain amplifier stage further comprises a high pass filter having an input electrically connected to an output of the variable gain amplifier of the at least one variable gain amplifier stage.

5: The circuit of claim 4 wherein an input of the high pass filter is an output of the at least one variable gain amplifier stage.

6: The circuit of claim 3 wherein the automatic gain controller is further configured to generate the switch control signal.

7: The circuit of claim 1 wherein each stage of the cascaded chain of variable gain amplifier stages comprises a switch module serving as input to the each stage, the variable gain amplifier, and a high pass filter serving as output for the each stage electrically connected in series in said order.

8: The circuit of claim 7 wherein the switch module is configured to electrically connect or disconnect an input of the variable gain amplifier to/from the output of a previous variable gain amplifier stage according to a switch control signal.

9: A method for RSSI estimation, the method comprising:
amplifying a received input signal using a cascaded chain of variable gain amplifier stages, each stage comprising a variable gain amplifier;
comparing output of the cascaded chain of variable gain amplifier stages with a predetermined threshold and outputting results of the comparison as an indication signal; and
adjusting gain of at least one variable gain amplifier of the cascaded chain of variable gain amplifier stages according to the indication signal.

10: The method of claim 9 further comprising electrically connecting or disconnecting an input of the variable gain amplifier of the at least one variable gain amplifier stage to/from an output of a previous variable gain amplifier stage according to a switch control signal.

11: The method of claim 10 further comprising electrically connecting the input of variable gain amplifier of the at least one variable gain amplifier stage to a predetermined DC voltage level when the input of the variable gain amplifier of at the least one variable gain amplifier stage is disconnected from the output of a previous variable gain amplifier stage.

12: The method of claim 9 further comprising utilizing the indication signal as an input basis to a binary search algorithm to determine level of gain adjustment of the at least one variable gain amplifier.

13: The method of claim 12 further comprising determining a gain value applied to the at least one variable gain amplifier to be stable and locking gain adjustment of the at least one variable gain amplifier when the indication signal has a same period pulse width at least two times.

14: The method of claim 12 further comprising not starting a state machine controlling the binary search algorithm until the input signal is received.

15: The method of claim 9 further comprising reinitializing the method at regular intervals.

16: The method for RSSI estimation of claim 9 further comprising transferring gain value information of a final gain into an RSSI value for output to outside application blocks.

17: The method for RSSI estimation of claim 16 further comprising adjusting gain of the at least one variable gain amplifier such that the final gain and a gain most nearly preceding the final gain will make polarity of the output of the threshold detector alternate except at a predefined lowest gain.

18: The circuit for RSSI estimation of claim 1 further comprising transferring gain value information of a final gain into an RSSI value for output to outside application blocks.

19: The circuit for RSSI estimation of claim 18 further comprising adjusting gain of the at least one variable gain amplifier such that the final gain and a gain most nearly preceding the final gain will make polarity of the output of the threshold detector alternate except at a predefined lowest gain.
